(19) United States
(12) Patent Application Publication
(10) Pub. No.: US 2019/0379358 A1
(43) Pub. Date: Dec. 12, 2019

(54) CASCADED INTEGRATOR-COMB (CIC) DECIMATION FILTER WITH INTEGRATION RESET TO SUPPORT A REDUCED NUMBER OF DIFFERENTIATORS

(71) Applicant: STMicroelectronics International N.V., Schiphol (NL)

(72) Inventors: Ankur BAL, Greater Noida (IN); Vikram SINGH, Radaur (IN); Harvinder SINGH, Greater Noida (IN)

(73) Assignee: STMicroelectronics International N.V., Schiphol (NL)

(21) Appl. No.: 16/416,482

(22) Filed: May 20, 2019

Related U.S. Application Data
(60) Provisional application No. 62/681,777, filed on Jun. 7, 2018.

(51) Int. Cl. H03H 17/06; H03H 17/02

(52) U.S. Cl. CPC H03H 17/0671; H03H 17/0251

(57) ABSTRACT

A cascaded integrator-comb (CIC) decimation filter includes N integrator stages, N−1 differentiator stages, and a decimator coupled to receive an integrated signal that is output from the N integrator stage and generate a decimated signal that is input to the N−1 differentiator stages. The decimator periodically asserts an integration reset signal. A last integrator stage of the N integrator stages is reset in response to assertion of the integration reset signal.

### CROSS-REFERENCE TO RELATED APPLICATION

This application claims the priority benefit of U.S. Provisional Application for Patent No. 62/681,777 filed Jun. 7, 2018, the disclosure of which is incorporated herein by reference.

### TECHNICAL FIELD

The present invention relates generally to a decimation filter and, more particularly, to an improved cascaded integrator-comb (CIC) decimation filter.

### BACKGROUND

Reference is now made to FIG. 1 which shows a schematic view of a conventional N-stage cascaded integrator-comb (CIC) decimation filter 10. A CIC decimation filter includes an equal number of stages of integrators 12 and differentiators (or combs) 16. In this example, there are N stages of integrators 12(1) to 12(N) and N stages of differentiators 16(1) to 16(N). The N integrators 12(1) to 12(N) are connected in series cascade with the (first) integrator 12(1) stage in the string having an input configured to receive an input signal IN (where the input signal IN is a digital signal and the integrators operate at a sampling frequency of the input digital signal). The output of the integrator 12(1) is coupled to the input of the next integrator 12(2) stage in the string, and this connectivity is repeated across the string of included integrator stages. The output of the (last) integrator 12(N) stage in the string produces an integration signal 20 that is applied to the input of a rate changer in the form of a decimator 14 (also referred to in the art as a down-sampler). The decimator 14 operates to decimate the integration signal 20 and generate a decimated signal 22. As an example, the decimator 14 may select for output as the decimated signal 22 every D-th sample of the integration signal 20 so as to provide a down sampling rate of D. The N differentiators 16(1) to 16(N) are connected in cascade series with the (first) differentiator 16(N) stage in the string having an input configured to receive the decimated signal 22. The output of the differentiator 16(N) is coupled to the input of the next differentiator 16(N−1) stage in the string, and this connectivity is repeated across the string of included differentiators. The output of the (last) differentiator 16(1) stage in the string produces an output signal OUT which is the result of filtering the input signal IN (where the output signal OUT is a digital signal and the differentiators operate at a sampling frequency of the output digital signal). The down sampling rate of D effectuates the rate change from the sampling frequency of the input digital signal to the sampling frequency of the output digital signal.

Each integrator 12, as shown schematically in FIG. 2, comprises an adder 30 having a first input configured to receive an input signal 32 and a second input configured to receive a delay signal 34. The adder 30 operates to add the delay signal 34 to the input signal 32. The output signal 36 from the adder 30 is applied to the input of a delay element 38 which generates the delay signal 34. The illustration of FIG. 2 is a very general representation of the functionality of the integrator 12.

Each differentiator 16, as shown schematically in FIG. 3, comprises a subtractor 40 having a first input configured to receive an input signal 42 and a second input configured to receive a delay signal 44. The subtractor 40 operates to subtract the delay signal 44 from the input signal 42 and generate an output signal 46. The delay signal 44 is generated at the output of a delay element 48 whose input also receives the input signal 42. The illustration of FIG. 3 is a very general representation of the functionality of the differentiator 16.

Let XNin be the signal at the input of the first integrator 12 in the string, and let n be the index of the samples of the signal x. XNin may be represented as:

XNin=x(0), x(1), x(2), . . . , x(n), . . . , x(n+k),

Let XNint be the integration signal 20 at the output of the last integrator 12(N). XNint may be represented as:

XNint=x(0), x(0)+x(1), x(0)+x(1)+x(2), . . . , x(0)+x(1)+ . . . +x(n),

Let XND be the decimated signal 22 at the output of the decimator 14. The decimator 14 functions to output every D-th sample of the signal XNint, which would represent the integration signal 20 at the samples where n=0, D, 2D, . . . .

XND may be represented as:

XND=X(0), X(D), X(2D),

where:

X(0)=x(0),

X(D)=x(0)+x(1)+ . . . +x(D),

X(2D)=x(0)+x(1)+ . . . +x(2D),

and so on.

Let XNout be the signal at the output of the (first) differentiator 16(N) in the string. XNout may be represented as:

XNout=X(D)−X(0), X(2D)−X(D), X(3D)−X(2D),

This may also be represented as follows:

XNout=Σₙ₌₀^{D}x(n)−x(0), Σ_{n=D}^{2D}x(n)−Σₙ₌₀^{D}x(n),

The foregoing may be graphically represented as shown in FIG. 4. The graph very generally shows an example of the accumulated values of the integrator 12(N) in the string at reference 42 for an example monotonically increasing input signal. The function of the differentiator 16(N) is to extract the difference portion indicated at reference 44 as XNout=X(k+D)−X(k).

There is a need in the art to reduce the size and power consumption of the CIC decimation filter with negligible or no associated performance penalty.

### SUMMARY

In an embodiment, a cascaded integrator-comb (CIC) decimation filter comprises: N integrator stages coupled in series; a decimator having an input coupled to receive an integrated signal that is output from the N stages of integrators coupled in series; N−1 differentiator stages coupled in series and configured to receive a decimated signal that is output from the decimator; wherein the N integrator stages coupled in series include a last integrator stage in the series having an output generating the integrated signal; and wherein the last integrator stage is controlled to periodically reset the integrated signal.

In an embodiment, a cascaded integrator-comb (CIC) decimation filter comprises: N integrator stages coupled in series; a decimator having an input coupled to receive an integrated signal that is output from the N integrator stages coupled in series and configured to periodically output samples of a decimated signal and periodically assert an integration reset signal; and N−1 differentiator stages coupled in series and configured to receive the decimated signal that is output from the decimator; wherein the integration reset signal is applied to a last integrator stage of said N integrator stages coupled in series to cause a feedback delay element of the last integrator stage to be reset to zero.

In an embodiment, a method comprises: integrating samples of an input digital signal to generate an integration signal; decimating samples of the integration signal to generate a decimation signal; differentiating samples of the decimation signal; and periodically resetting the integration signal.

### BRIEF DESCRIPTION OF THE DRAWINGS

For a better understanding of the embodiments, reference will now be made by way of example only to the accompanying figures in which:

FIG. 1 shows a schematic view of a conventional N-stage cascaded integrator-comb (CIC) decimation filter;

FIG. 2 shows a schematic view of a conventional integrator stage within the CIC decimation filter of FIG. 1;

FIG. 3 shows a schematic view of a conventional differentiator stage within the CIC decimation filter of FIG. 1;

FIG. 4 graphically illustrates operation of the CIC decimation filter of FIG. 1;

FIG. 5 shows a schematic view of an improved N-stage cascaded integrator-comb (CIC) decimation filter with a reduced number of differentiators;

FIG. 6 graphically illustrates operation of the CIC decimation filter of FIG. 5; and

FIG. 7 shows a schematic view of a last integrator stage within the CIC decimation filter of FIG. 5.

### DETAILED DESCRIPTION

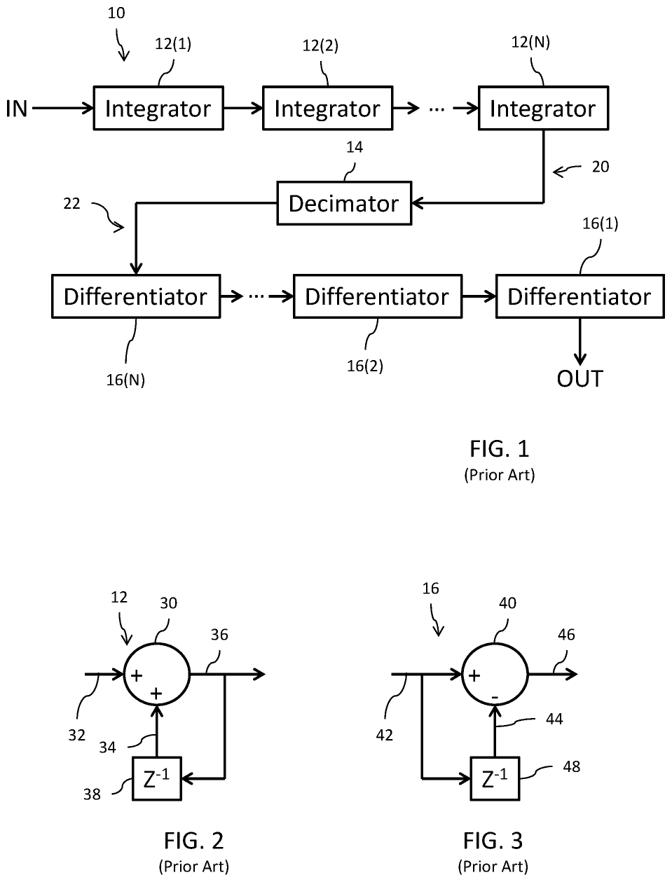

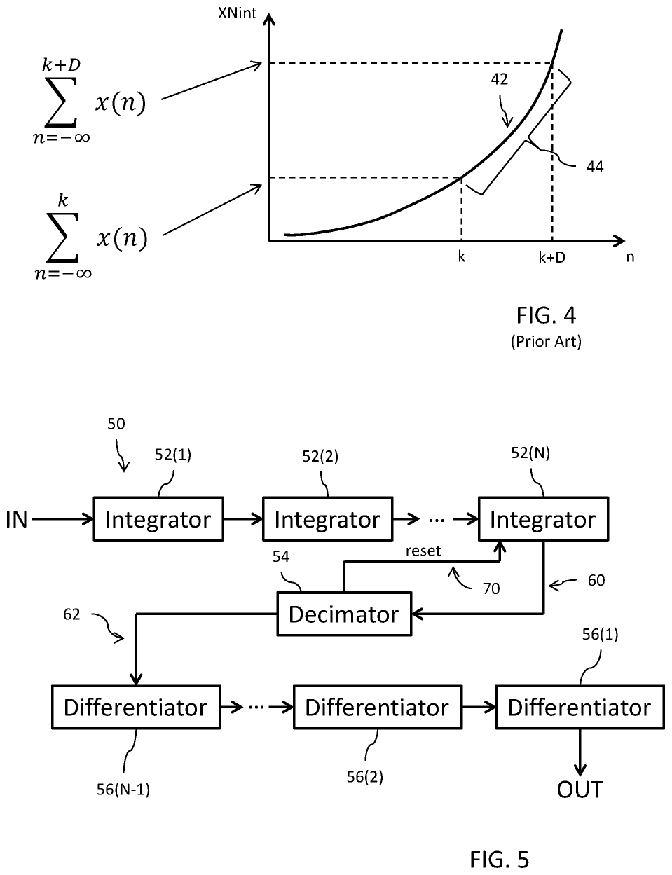

Reference is now made to FIG. 5 which shows a schematic view of an N-stage cascaded integrator-comb (CIC) decimation filter 50. While the conventional CIC decimation filter 10 as shown in FIG. 1 includes an equal number of stages of integrators 12 and differentiators (or combs) 16, the CIC decimation filter 50 as shown in FIG. 5 is instead implemented with an unequal number of stages. More specifically, the CIC decimation filter 50 includes N integration stages and N−1 differentiation stages. The integration stages are provided by N integrators 52(1) to 52(N) and the differentiation stages are provided by N−1 differentiators 56(1) to 56(N−1).

The N stages of integrators 52(1) to 52(N) are connected in cascade series with the (first) integrator 52(1) in the string having an input configured to receive an input signal IN (where the input signal IN is a digital signal and the integrators operate at a sampling frequency of the input digital signal). The output of the integrator 52(1) is coupled to the input of the next integrator 52(2) stage in the string, and this connectivity is repeated across the string of included integrators. The output of the (last) integrator 52(N) stage in the string produces an integration signal 60 that is applied to the input of a rate changer in the form of a decimator 54 (also referred to in the art as a down-sampler). The decimator 54 operates to decimate the integration signal 60 and generate a decimated signal 62. As an example, the decimator 54 may select for output as the decimated signal 62 every D-th sample of the integration signal 60 so as to provide a down sampling rate of D. The N−1 stages of differentiators 56(1) to 56(N−1) are connected in cascade series with the (first) differentiator 56(N−1) stage in the string having an input configured to receive the decimated signal 62. The output of the differentiator 56(N−1) is coupled to the input of the next differentiator 56(N−2) stage in the string, and this connectivity is repeated across the string of included differentiators. The output of the (last) differentiator 56(1) stage in the string produces an output signal OUT which is the result of filtering the input signal IN (where the output signal OUT is a digital signal and the differentiators operate at a sampling frequency of the output digital signal). The down sampling rate of D effectuates the rate change from the sampling frequency of the input digital signal to the sampling frequency of the output digital signal.

Each integrator 52, except for the last integrator 52(N), may be implemented as shown schematically in FIG. 2 with respect to integrator 12. FIG. 7 shows a schematic view of the last integrator 52(N). The last integrator 52(N) is substantially the same as the integrator 12 of FIG. 2, except that the delay element 38′ is resettable to zero in response to a reset signal 70. In response to assertion of the reset signal 70, the feedback delay signal 34 is set to zero, and thus the output of the adder 30 when this occurs would be zero plus the input signal 32.

Each differentiator 56 may be implemented as shown schematically in FIG. 3 with respect to differentiator 16.

The reset signal 70 is generated by the decimator 54 once every D counts of the decimation operation. In other words, the reset signal 70 is asserted each time the decimator 54 outputs a new sample of the decimated signal 62. In response to the assertion of the reset signal 70, the last integrator 52(N) is reset and the integration signal 60 output from the last integrator 52(N) has a feedback delay contribution of zero. The implementation of the reset operation may be accomplished, as discussed herein with respect to an integrator of the type shown in FIG. 7, by resetting a data register associated with the feedback loop of the integrator 52(N) to zero so that next sample of the integration signal 60 is zero plus the output of the (N−1)-th integrator in the string.

It will be noted that the last integrator 52(N) in the string has a non-modulo implementation which is different from the modulo integrator operation of the integrators 12 of the CIC decimation filter 10 of FIG. 1. The resetting of the last integrator 52(N) every D-th samples will preclude an overflow from occurring.

Let XNin be the signal at the input of the first integrator 52 in the string, and let n be the index of the samples of the signal x. XNin may be represented as:

XNin=x(0), x(1), x(2), . . . , x(n), . . . , x(n+k),

Let XNint be the integration signal 60 at the output of the last integrator 52(N). It will be remembered that the last integrator 52(N) is reset once every D counts. XNint may be represented as:

For counts 0 to D; XNint=x(0), x(0)+x(1), x(0)+x(1)+x(2), . . . , x(0)+x(1)+ . . . +x(D)

For counts D+1 to 2D; XNint=x(D+1), x(D+1)+x(D+2), x(D+1)+x(D+2)+x(D+3), . . . , x(D+1)+x(D+2)+ . . . +x(2D).

For counts 2D+1 to 3D; XNint=x(2D+1), x(2D+1)+x(2D+2), x(2D+1)+x(2D+2)+x(2D+3), . . . , x(2D+1)+x(2D+2)+ . . . +x(3D). And so on.

Let XND be the decimated signal 62 at the output of the decimator 54. The decimator 54 functions to output every D-th sample of the signal XNint, which would represent the integration signal 20 at the samples where n=0, D, 2D, . . . .

XND=X(0), X(D), X(2D),

where:

X(0)=XNint(0)=x(0),

X(D)=XNint(D)=x(1)+ . . . +x(D),

X(2D)=XNint(2D)=x(D+1)+x(D+2)+ . . . +x(2D),

X(3D)=XNint(3D)=x(2D+1)+x(2D+2)+ . . . +x(3D),

and so on.

This may also be represented as follows:

XND=Σₙ₌₀^{D}x(n)−x(0), Σ_{n=D}^{2D}x(n)−Σₙ₌₀^{D}x(n),

Notably, this XND output is equal to the XNout output from the first differentiator 16(N) of the of the CIC decimation filter 10 of FIG. 1.

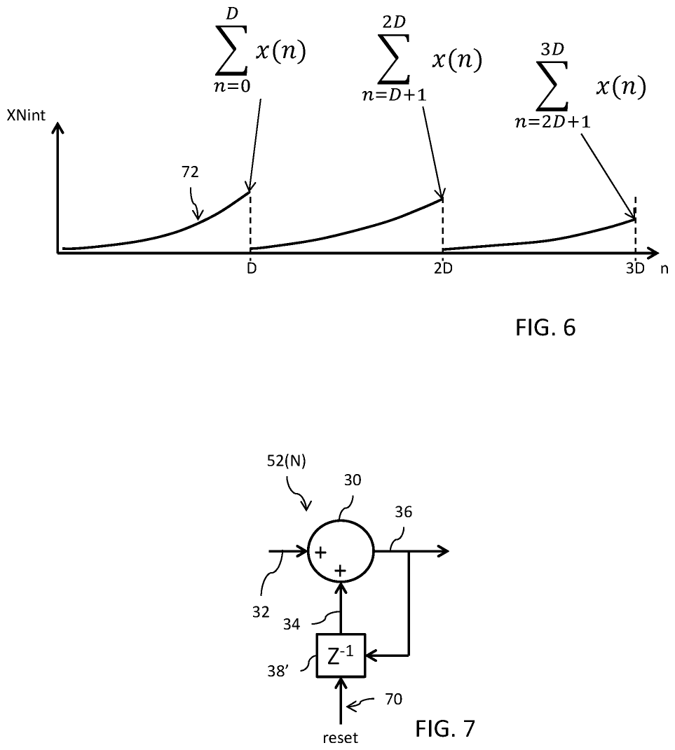

The foregoing may be graphically represented as shown in FIG. 6. The graph very generally shows an example of the accumulated values of the last integrator 52(N) in the string at reference 72. The integration operation is reset every D-th sample and the integration starts over again from the current input signal value. Because of this, the last integrator 52(N) output will always represent the difference between consecutive D-th samples. It will be recalled that the calculation of this different is the function performed by the first differentiator 16(N) of the CIC decimation filter 10 of FIG. 1. Due to the resetting of the last integrator 52(N) as provided by the CIC decimation filter 50 of FIG. 5, it is possible to eliminate the need for the first differentiator 16(N) in the conventional CIC decimator filter 10 and this is why the CIC decimation filter 50 of FIG. 5 includes only (N−1) differentiators 56.

It will be noted that the example shown in FIG. 7 is correct for the case of a monotonically rising input signal only. This is, of course, just one of many possibilities (rising, falling, mixed, etc.) and thus is only an example presented to illustrate the concept of the effect of periodically resetting the last integrator.

The implementation of the CIC decimation filter 50 of FIG. 5 provides a number of advantages over prior art CIC implementations. The advantages include: a) there is no need for an extra data path; b) there is no control penalty; c) the circuit occupies less space and operates at a reduced power level; d) there is support for multiple decimation rate modes (i.e., D can be programmed to any value without area penalty as only the time of reset is being altered and the remainder of the circuit stays the same); e) there is an elimination of one differentiator in comparison to prior art CIC filters; and f) performance is identical to the prior art CIC filter at least because the system transfer function is same.

The system of FIG. 5 can be implemented in any suitable hardware, software, firmware, or a combination thereof, without departing from the scope of the invention.

The system may include a processor and a memory, the memory having the computer executable instructions for executing a process for implementing the CIC filtering operation. The computer executable instructions, in whole or in part, may also be stored on a computer readable medium separated from the system on which the instructions are executed. The computer readable medium may include any volatile or non-volatile storage medium such as flash memory, compact disc memory, and the like.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A cascaded integrator-comb (CIC) decimation filter, comprising:
N integrator stages coupled in series;
a decimator having an input coupled to receive an integrated signal that is output from the N integrator stages coupled in series;
N−1 differentiator stages coupled in series and configured to receive a decimated signal that is output from the decimator;
wherein the N integrator stages coupled in series include a last integrator stage in the series having an output generating the integrated signal; and
wherein the last integrator stage is controlled to be periodically reset.

2. The CIC decimation filter of claim 1, wherein the last integrator stage responds to being periodically reset by accumulating a zero value instead of a delayed value.

3. The CIC decimation filter of claim 1, wherein the N integrator stages operate at a first sampling frequency of an input digital signal and wherein the N−1 differentiator stages operate at a second sampling frequency of an output digital signal.

4. The CIC decimation filter of claim 3, wherein the decimator effectuates a rate change from the first sampling frequency to the second sampling frequency.

5. The CIC decimation filter of claim 1, wherein the decimator is configured to periodically assert a reset signal which causes the last integrator stage to be periodically reset.

6. The CIC decimation filter of claim 5, wherein the reset signal is asserted in conjunction with each output of a sample of the decimated signal.

7. The CIC decimation filter of claim 5, wherein the reset signal is asserted at a same rate as a rate change implemented by the decimator.

8. The CIC decimation filter of claim 1, wherein the last integrator stage includes a feedback delay element, and wherein the periodic reset of the last integrator stage causes an output of the feedback delay element to be set to zero.

9. A cascaded integrator-comb (CIC) decimation filter, comprising:
N integrator stages coupled in series;
a decimator having an input coupled to receive an integrated signal that is output from the N integrator stages coupled in series and configured to periodically output samples of a decimated signal and periodically assert an integration reset signal; and
N−1 differentiator stages coupled in series and configured to receive the decimated signal that is output from the decimator;
wherein the integration reset signal is applied to a last integrator stage of said N integrator stages coupled in series to cause a feedback delay element of the last integrator stage to be reset to zero.

10. The CIC decimation filter of claim 9, wherein said one integrator stage is a last integrator stage of said N integrator stages coupled in series.

11. The CIC decimation filter of claim 9, wherein the N integrator stages operate at a first sampling frequency of an input digital signal and wherein the N−1 differentiator stages operate at a second sampling frequency of an output digital signal.

12. The CIC decimation filter of claim 11, wherein the decimator effectuates a rate change from the first sampling frequency to the second sampling frequency.

13. The CIC decimation filter of claim 9, wherein the integration reset signal is asserted in conjunction with each output of a sample of the decimated signal.

14. The CIC decimation filter of claim 9, wherein the integration reset signal is asserted at a same rate as a rate change implemented by the decimator.

15. A method, comprising:
integrating samples of an input digital signal to generate an integration signal;
decimating samples of the integration signal to generate a decimation signal;
differentiating samples of the decimation signal; and
periodically resetting the integration signal.

16. The method of claim 15, wherein periodically resetting comprises accumulating a zero value instead of a delayed value.

17. The method of claim 15, further comprising:
periodically generating an integration reset signal at a same rate as the samples of the integration signal are being decimated to generate the decimation signal; and
wherein periodically resetting comprises resetting the integration signal in response to each integration reset signal.

18. The method of claim 15, wherein integrating operates at a first sampling frequency of the input digital signal and wherein differentiating operates at a second sampling frequency of an output digital signal.

19. The method of claim 18, wherein decimating effectuates a rate change from the first sampling frequency to the second sampling frequency.

20. The method of claim 19, wherein periodically resetting is performed at a same rate as the rate change.

21. The method of claim 15, wherein periodically resetting comprises resetting a feedback delay signal of an integration operation to zero.

22. The method of claim 21, wherein the feedback delay signal is reset to zero in response to each decimated signal sample output.
